(19) United States
(12) Patent Application Publication
(10) Pub. No.: US 2008/0311524 A1
(43) Pub. Date: Dec. 18, 2008

(54) Method For Making Negative-Working Heat-Sensitive Lithographic Printing Plate Precursor

(75) Inventors: Joan Vermeersch, Deinze (BE); Johan Loccufier, Zwijnaarde (BE); Paul Callant, Edegem (BE); Jurgen Jung, Aartselaar (BE); Marc Van Damme, Bonheiden (BE)

Correspondence Address: AGFA;c/o KEATING & BENNETT, LLP, 1800 Alexander Bell Drive, SUITE 200, Reston, VA, 20191, US

(73) Assignee: AGFA GRAPHICS N.V., Mortsel (BE)

(21) Appl. No.: 11/571,784

(22) PCT Filed: Jul. 1, 2005
(86) PCT No.: PCT/EP05/53141

§ 371 Date: Jul. 26, 2007

Related U.S. Application Data
(60) Provisional application No. 60/587,314, filed on Jul. 13, 2004.

(30) Foreign Application Priority Data
Jul. 8, 2004 (EP) 04103252.5

(51) Int. Cl. G03F 7/20; B41N 1/00

(52) U.S. Cl. 430/302; 427/144

(57) ABSTRACT

A method for making a negative-working heat-sensitive lithographic printing plate precursor includes the steps pf:
(i) providing a support having a hydrophilic surface or which is provided with a hydrophilic layer; and
(ii) applying on the support a coating which includes a product DQ, wherein DQ is obtained by:
the step of coating a solution or dispersion including a nucleophilic compound Q and a dye D selected from the list consisting of di- or tri-arylmethane dyes, cyanine dyes, styryl dyes, and merostyryl dyes; or by
D and Q interact to form interaction product DQ, having a white light optical density which is lower that the white light optical density of dye D; and
the interaction product DQ is capable of at least partially releasing a dye directly after exposure to infrared light or heat, therby forming a visible image in the coating.

### FIELD OF THE INVENTION

The present invention relates to a method for making a negative-working heat-sensitive lithographic printing plate precursor whereby a visible image directly after image-wise heating is obtained. The present invention relates also to a method for making a lithographic printing plate.

### BACKGROUND OF THE INVENTION

Lithographic printing typically involves the use of a so-called printing master such as a printing plate which is mounted on a cylinder of a rotary printing press. The master carries a lithographic image on its surface and a print is obtained by applying ink to said image and then transferring the ink from the master onto a receiver material, which is typically paper. In conventional lithographic printing, ink as well as an aqueous fountain solution (also called dampening liquid) are supplied to the lithographic image which consists of oleophilic (or hydrophobic, i.e. ink-accepting, water-repelling) areas as well as hydrophilic (or oleophobic, i.e. water-accepting, ink-repelling) areas. In so-called driographic printing, the lithographic image consists of ink-accepting and ink-abhesive (ink-repelling) areas and during driographic printing, only ink is supplied to the master.

Printing masters are generally obtained by the image-wise exposure and processing of an imaging material called plate precursor. A typical positive-working plate precursor comprises a hydrophilic support and an oleophilic coating which is not readily soluble in an aqueous alkaline developer in the non-exposed state and becomes soluble in the developer after exposure to radiation. In addition to the well known photosensitive imaging materials which are suitable for UV contact exposure through a film mask (the so-called pre-sensitized plates), also heat-sensitive printing plate precursors have become very popular. Such thermal materials offer the advantage of daylight stability and are especially used in the so-called computer-to-plate method (CtP) wherein the plate precursor is directly exposed, i.e. without the use of a film mask. The material is exposed to heat or to infrared light and the generated heat triggers a (physico-)chemical process, such as ablation, polymerization, insolubilization by cross-linking of a polymer or by particle coagulation of a thermoplastic polymer latex, and solubilization by the destruction of intermolecular interactions or by increasing the penetrability of a development barrier layer.

It is important in the printing plate preparation work that the exposed plate precursor shows a visible image even before being developed, i.e. a print-out image. This enables the end-user to establish immediately whether or not the precursor is already exposed to light, to inspect images on the printing plate and to distinguish the plate to which color of inks should be applied. In such a work flow the exposed printing plate are developed later in a separate developing step or in an on-press processing step.

On-press processing is disclosed in EP 770 494, wherein the plate is mounted on the press and the coating layer is developed by interaction with the fountain and ink that are supplied to the cylinder during the press run. During the first runs of the press, the non-exposed areas (for a negative-working precursor) are removed from the support and thereby define the non-printing areas of the plate. Since development of the plate is not carried out before starting the printing process, a previous inspection and discrimination of the plate is not possible unless the formation of a print-out image.

Several methods for formation of a print-out image are known for photopolymer systems such as disclosed in U.S. Pat. No. 3,359,109, U.S. Pat. No. 3,042,515, U.S. Pat. No. 4,258,123, U.S. Pat. No. 4,139,390, U.S. Pat. No. 5,141,839, U.S. Pat. No. 5,141,842, U.S. Pat. No. 4,232,106, U.S. Pat. No. 4,425,424, U.S. Pat. No. 5,030,548, U.S. Pat. No. 4,598,036, EP 0 434 968 and WO 96/35143. In these materials the photoinitiating system is a reacting component which induces formation of the print-out image upon exposure and therefore the performance of the lithographic differentiation process is reduced.

DD 213 530 discloses a method for preparing a printing plate wherein a sensitiser is used whereof the optical density is reduced upon heating by laser exposure.

EP 897 134 discloses a method for making a positive-working photosensitive lithographic printing plate wherein the positive photosensitive composition comprises dye formed by an interaction between an alkali-soluble organic high molecular substance having phenolic hydroxyl groups and an acid color forming dye and wherein a positive image is formed by discoloration of the formed dye upon exposure.

EP 0 925 916 discloses a method for preparing a lithographic printing plate wherein the heat-sensitive coating comprises an IR-cyanine dye as light to heat conversion agent, whereof the visual optical density is decreased upon laser recording.

EP 1 300 241 discloses a lithographic printing plate precursor comprising a support and a layer containing a heat decomposable dye having an absorption maximum wavelength in a visible region, and not substantially having an absorption in an oscillation wavelength of a laser used for heat mode exposure.

WO2004/017139 discloses a negative-working photosensitive composition (a) an alkali-soluble resin, (b) a compound which causes a crosslinking reaction by an acid, (c) a compound which generates an acid by heating, and (d) a photothermal converting agent, wherein the compound (c) is an onium salt of an acidic dye having a sulphonic group; at the time of exposure the acid of the onium salt reacts with the acidic dye and the color difference between exposed and non-exposed areas are enhanced, resulting in improvement of visible image properties.

U.S. Pat. No. 6,132,935 discloses a negative-working image recording material which comprises a substance which absorbs light to generate heat, a water-insoluble and aqueous alkali-soluble resin, and a phenol derivative having a specific structure. The material can further contain a printing-out agent for providing a visible image immediately after the heat-generation due to exposure. The printing-out agent is a combination of a compound which releases an acid when heated and an organic dye capable of forming a salt.

The visible image which is obtained directly after exposure, herein also referred to as “print-out image”, is generated in the prior art thermal plate materials by a bleaching process of a dye and, for positive working printing plates, this results in a decreased visual optical density on the exposed areas (these areas corresponds to the water-accepting areas on the plate), and the image polarity of the print-out is the same as the image obtained in the printing process.

For negative-working printing plates, such a bleaching process results in a print-out image which has a reversed image polarity than the image obtained in the printing process and this is difficult for the end-user to inspect the quality of the image on the printing plate precursor and to decide whether it has to be remade. Therefore, there is a need for systems which build-up an increased optical density on the exposed areas. In the prior art, systems which build-up an increased color by image-wise exposure with visible light or UV light are known, but in these systems the reacting components for the formation of the print-out image are also used for the formation of the lithographic differentiation in the plate, resulting in a reduced lithographic performance of the printing plate precursor. Therefore, there is a need for print-out systems which are able to build-up an increased optical density on the heat exposed areas by other components than those used for the formation of a lithographic differentiation process of a negative-working heat-sensitive printing plate, especially for a negative-working heat-sensitive printing plate which is developed by an on-press processing.

### SUMMARY OF THE INVENTION

It is an object of the present invention to provide a method for making a negative-working heat-sensitive lithographic printing plate precursor which is capable of providing, directly after image-wise heating, a visible image having the same image polarity as the corresponding image in the printing process. This object is realized by the method as defined in claim 1, having the characteristic feature that the coating of the precursor comprises a product DQ, wherein DQ is obtained by the step of coating a solution or dispersion comprising a nucleophilic compound Q and a dye D selected from the list consisting of di- or tri-arylmethane dyes, cyanine dyes, styryl dyes and merostyryl dyes, or by the step of coating a solution or dispersion comprising said compound Q and coating another solution or dispersion comprising said dye D, and wherein D and Q interact to form interaction product DQ, having a white light optical density which is lower than the white light optical density of dye D, and wherein said interaction product DQ is capable of at least partially releasing a dye directly after exposure to infrared light or heat, thereby forming a visible image in said coating.

Other specific embodiments of the invention are defined in the dependent claims.

### BRIEF DESCRIPTION OF THE DRAWING

FIG. 1 shows the spectral density curves of the coating without Q, with Q and with Q after laser exposure for Invention Example 2 and Comparative example 2.

### DETAILED DESCRIPTION OF THE INVENTION

In accordance with the present invention, there is provided a method for making a negative-working heat-sensitive lithographic printing plate precursor comprising the steps of

(i) providing a support having a hydrophilic surface or which is provided with a hydrophilic layer, and
(ii) applying on said support a coating which comprises a product DQ, wherein DQ is obtained by
the step of coating a solution or dispersion comprising a nucleophilic compound Q and a dye D selected from the list consisting of di- or tri-arylmethane dyes, cyanine dyes, styryl dyes and merostyryl dyes; or by
the step of coating a solution or dispersion comprising said compound Q and coating another solution or dispersion comprising said dye D;
   wherein D and Q interact to form interaction product DQ, having a white light optical density which is lower than the white light optical density of dye D, and
   wherein said interaction product DQ is capable of at least partially releasing a dye directly after exposure to infrared light or heat, thereby forming a visible image in said coating.

The white light optical density of the interaction product DQ and of the dye D are hereinafter also referred to as “WLOD-DQ” and as “WLOD-D”. The coating is hereinafter also referred to as “heat-sensitive coating”.

In a preferred embodiment of the present invention, the visible image formed directly after exposure to infrared light or heat is characterised by a decrease of the CIE 1976 lightness of the exposed areas, L*-exp, compared to the CIE 1976 lightness of the non-exposed areas L*-nexp, and/or by an increase of the CIE 1976 chroma of the exposed areas, C*-exp, compared to the CIE 1976 chroma of the non-exposed areas, C*-nexp, and by a value of at least 3 for the CIE 1976 color distance ΔE, measured between the exposed and non-exposed areas.

“Directly after exposure” means that the coating has not been developed.
“WLOD-DQ” is defined as the integrated absorption spectrum of optical density versus wavelength in the full range between 400 and 730 nm of the coating comprising interaction product DQ before exposure.
“WLOD-D” is defined as the integrated absorption spectrum of optical density versus wavelength in the full range between 400 and 730 nm of the coating comprising dye D without Q before exposure. L*-exp is defined as the CIE 1976 lightness of the exposed areas and L*-nexp as the CIE 1976 lightness of the non-exposed areas. C*-exp is defined as the CIE 1976 chroma of the exposed areas and C*-nexp as the CIE 1976 chroma of the non-exposed areas.
The CIE color coordinates: L* (lightness), a*, b*, C* (chroma) and ΔE (color distance) are defined as described by CIE 15.2-1986: Colorimetry, CIE 116-1995: Industrial Colour Difference Evaluation, or R. W. G. Hunt in MEASURING COLOUR, second edition, edited in 1992 by Ellis Horwood Limited, England, and are calculated from the spectral density curve of the exposed and non-exposed areas following the “CIE 1976 Colour Difference” formulae as described in the same document.
Herein, the following definitions are used:

ΔL*=[(L*-nexp)−(L*-exp)],

ΔC*=[(C*-exp)−(C*-nexp)],

C* is calculated from the a* and b* values as C*=[(a)²+(b)²]^{1/2},

ΔE=[(ΔL*)²+(ΔC*)²]^{1/2}.

Typically, the 2 degree observer (CIE 1931) is taken into account. These measurements and calculations are preferably carried following the ASTM E308 method. Any illuminant may be used; typically, D65 or F6, i.e. cool white fluorescent lamp with yellow filter, are used in these measurements and calculations.

The contrast of the print-out image formed upon infrared light exposure or heating is preferably as high as possible. According to the present invention, a high contrast is obtained by a decrease of L*-exp compared to L*-nexp or by an increase of C*-exp compared to C*-nexp or, most preferably, by a combination of both, resulting in a color distance ΔE between the exposed and non-exposed areas of at least 3, preferably at least 4, more preferably at least 8 and most preferably at least 10. The decrease of L*-exp compared to L*-nexp is defined by [(L*-nexp)−(L*-exp)] and is preferably at least 2, more preferably at least 3, most preferably at least 6; and the increase of C*-exp compared to C*-nexp is defined by [(C*-exp)−(C*-nexp)] and is preferably at least 1.2, more preferably at least 2, most preferably at least 2.5.

In another preferred embodiment, the decrease of WLOD-DQ compared to the WLOD-D, defined as (WLOD-D−WLOD-DQ). 100%/WLOD-D, is at least 25%, more preferably at least 30%, most preferably at least 40%.

According to another preferred embodiment of the present invention, the dye D is a di- or tri-arylmethane dye wherein an aryl group is substituted with an amino group, hereinafter also referred to as a “amino substituted di- or tri-aryl methane dye”.

Specific examples of such amino substituted di- or tri-aryl methane dyes and other suitable dyes are given in the following list. In this list the dyes are mentioned in their reduced form (also called “leuco form” or “leuco dye”) having one or two hydrogen atoms, the removal of which together with one or two electrons produces the dyes D which are suitable in the present invention:

### A. Aminotriarylmethanes

bis(4-amino-2-butylphenyl)(p-dimethylaminophenyl)-methane
bis(4-amino-2-chlorophenyl)(p-aminophenyl)methane
bis(4-amino-3-chlorophenyl)(o-chlorophenyl)methane
bis(4-amino-3-chlorophenyl)phenylmethane
bis(4-amino-3,5-diethylphenyl)(o-chlorophenyl)-methane
bis(4-amino-3,5-diethylphenyl)(o-ethoxyphenyl)-methane
bis(4-amino-3,5-diethylphenyl)(P-methoxyphenyl)-methane
bis(4-amino-3,5-diethylphenyl)phenylmethane
bis(4-amino-ethylphenyl)(o-chlorophenyl)methane
bis(p-aminophenyl)(4-amino-m-tolyl)methane
bis(p-aminophenyl)(o-chlorophenyl)methane
bis(p-aminophenyl)(p-chlorophenyl)methane
bis(p-aminophenyl)(2,4-dichlorophenyl)methane
bis(p-aminophenyl)(2,5-dichlorophenyl)methane
bis(p-aminophenyl)(2,6-dichlorophenyl)methane
bis(p-aminophenyl)phenylmethane-9-methylacridine
bis(4-amino-tolyl)(p-chlorophenyl)methane
bis(4-amino-o-tolyl)(2,4-dichlorophenyl)methane
bis(p-aminophenyl)(4-amino-m-tolyl)methane
bis(4-benzylamino-2-cyanophenyl)(p-aminophenyl)methane
bis(p-benzylethylaminophenyl)(p-chlorophenyl)methane
bis(p-benzylethylaminophenyl)(p-diethylaminophenyl)methane
bis(p-benzylethylaminophenyl)(p-dimethylaminophenyl)methane
bis(4-benzylethylamino-o-tolyl)(p-methoxyphenyl)methane
bis(p-benzylethylaminophenyl)phenylmethane
bis(4-benzylethylamino-o-tolyl)(o-chlorophenyl)methane
bis(4-benzylethylamino-o-tolyl)(p-diethylaminophenyl)methane
bis(4-benzylethylamino-o-tolyl)(4-diethylamino-o-tolyl)methane
bis(4-benzylethylamino-o-tolyl)(p-dimethylaminophenyl)methane
bis[2-chloro-4-(2-diethylaminoethyl)ethylaminophenyl]-(o-chlorophenyl)methane
bis[p-bis(2-cyanoethyl)aminophenyl]phenylmethane
bis[p-(2-cyanoethyl)ethylamino-o-tolyl](p-dimethylaminophenyl)methane
bis[p-(2-cyanoethyl)methylaminophenyl](p-diethylaminophenyl)methane
bis(p-dibutylaminophenyl) [p-(2-cyanoethyl)methylaminophenyl]methane
bis(p-dibutylaminophenyl)(p-diethylaminophenyl)methane
bis(4-diethylamino-2-butoxyphenyl)(p-diethylaminophenyl)methane
bis(4-diethylamino-2-fluorophenyl)-o-tolylmethane
bis(p-diethylaminophenyl)(p-aminophenyl)methane
bis(p-diethylaminophenyl)(4-anilino-1-naphthyl)methane
bis(p-diethylaminophenyl)(m-butoxyphenyl)methane
bis(p-diethylaminophenyl)(o-chlorophenyl)methane
(p-diethylaminophenyl)(p-cyanophenyl)methane
bis(p-diethylaminophenyl)(2,4-dichlorophenyl)methane
bis(p-diethylaminophenyl)(4-diethylamino-1-naphthyl)methane
bis(p-diethylaminophenyl)(p-dimethylaminophenyl)methane
bis(p-diethylaminophenyl)(4-ethylamino-1-naphthyl)methane
bis(p-diethylaminophenyl)-2-naphthylmethane
bis(p-diethylaminophenyl)(p-nitrophenyl)methane
bis(p-diethylaminophenyl)-2-pyridylmethane
bis(p-diethylamino-m-tolyl)(p-diethylaminophenyl)methane
bis(4-diethylamino-o-tolyl)(o-chlorophenyl)methane
bis(4-diethylamino-o-tolyl)(p-diethylaminophenyl)methane
bis(4-diethylamino-o-tolyl)(diphenylaminophenyl)methane
bis(4-diethylamino-o-tolyl)phenylmethane
bis(4-dimethylamino-2-bromophenyl)phenylmethane
bis(p-dimethylaminophenyl)(4-amino-1-naphthyl)methane
bis(p-dimethylaminophenyl)(p-butylaminophenyl)methane
bis(p-dimethylaminophenyl)(p-scc. butylethylaminophenyl)methane
bis(p-dimethylaminophenyl)(p-chlorophenyl)methane
bis(p-dimethylaminophenyl)(p-diethylaminophenyl)methane
bis(p-dimethylaminophenyl)(4-dimethylamino-1-naphthyl)methane
bis(p-dimethylaminophenyl)(6-dimethylamino-m-tolyl)methane
bis(p-dimethylaminophenyl)(4-dimethylamino-o-tolyl)methane
bis(p-dimethylaminophenyl)(4-ethylamino-1-naphthyl)methane
bis(p-dimethylaminophenyl)(p-hexyloxyphenyl)methane
bis(p-dimethylaminophenyl)(p-methoxyphenyl)methane
bis(p-dimethylaminophenyl)(5-methyl-2-pyridyl)methane
bis(4-diethylamino-2-ethoxyphenyl)(4-diethylamino phenyl)methane
bis(p-dimethylaminophenyl)-2-quinolylmethane
bis(p-dimethylaminophenyl)-o-tolylmethane
bis(p-dimethylaminophenyl))1,3,3-trimethyl-2-indolinylidenemethyl)methane
bis(4-dimethylamino-o-tolyl)(p-aminophenyl)methane
bis(4-dimethylamino-o-tolyl)(o-bromophenyl)methane
bis(4-dimethylamino-o-tolyl)(o-cyanophenyl)methane
bis(4-dimethylamino-o-tolyl)(o-fluorophenyl)methane
bis(4-dimethylamino-o-tolyl)-1-naphthylmethane
bis(4-dimethylamino-o-tolyl)phenylmethane
bis(p-ethylaminophenyl)(o-chlorophenyl)methane
bis(4-ethylamino-m-tolyl)(o-methoxyphenyl)methane
bis(4-ethylamino-m-tolyl)(p-methoxyphenyl)methane
bis(4-ethylamino-m-tolyl)(p-dimethylaminophenyl)methane
bis(4-ethylamino-m-tolyl)(p-hydroxyphenyl)methane
bis[4-ethyl(2-hydroxyethyl)amino-m-tolyl](p-diethylaminophenyl)methane
bis[p-(2-hydroxyethyl)aminophenyl](o-chlorophenyl)methane
bis[p-bis(2-hydroxyethyl)aminophenyl](4-diethylamino-o-tolyl)methane
bis[p-(2-methoxyethyl)aminophenyl]phenylmethane
bis(p-methylaminophenyl)(o-hydroxyphenyl)methane
bis(p-propylaminophenyl)(m-bromophenyl)methane
tris(4-amino-o-tolyl)methane
tris(4-anilino-o-tolyl)methane
tris(p-benzylaminophenyl)methane
tris[4-bis(2-cyanoethyl)amino-o-tolyl]methane
tris[p-(2-cyanoethyl)ethylaminophenyl]methane
tris(p-dibutylaminophenyl)methane
tris(p-di-t-butylaminophenyl)methane
tris(p-dimethylaminophenyl)methane
tris(4-diethylamino-2-chlorophenyl)methane
tris(p-diethylaminophenyl)methane
tris(4-diethylamino-o-tolyl)methane
tris(p-dihexylamino-o-tolyl)methane
tris(4-dimethylamino-o-tolyl)methane
tris(p-hexylaminophenyl)methane
tris[p-bis(2-hydroxyethyl)aminophenyl]methane
tris(p-methylaminophenyl)methane
tris(p-dioctadecylaminophenyl)methane

### B. Aminoxanthenes

3-amino-6-dimethylamino-2-methyl-9-(o-chlorophenyl)xanthene
3-amino-6-dimethylamino-2-methyl-9-phenylxanthene
3-amino-6-dimethylamino-2-methylxanthene
3,6-bis(diethylamino)-9-(o-chlorophenyl)xanthene
3,6-bis(diethylamino)-9-hexylxanthene
3,6-bis(diethylamino)-9-(o-methoxycarbonylphenyl)xanthene
3,6-bis(diethylamino)-9-methylxanthene
3,6-bis(diethylamino)-9-phenylxanthene
3,6-bis(diethylamino)-9-o-tolyxanthene
3,6-bis(dimethylamino)-9-(o-chlorophenyl)xanthene
3,6-bis(dimethylamino)-9-ethylxanthene
3,6-bis(dimethylamino)-9-(o-methoxycarbonylphenyl)xanthene
3,6-bis(dimethylamino)-9-methylxanthene

### C. Aminothioxanthenes

3,6-bis(diethylamino)-9-(o-ethoxycarbonylphenyl)thioxanthene
3,6-bis(dimethylamino)-9-(o-methoxycarbonylphenyl)thioxanthene
3,6-bis(dimethylamino)thioxanthene
3,6-dianilino-9-(o-ethoxycarbonylphenyl)thioxanthene
   D. Amino-9,10-dihydroacridines
3,6-bis(benzylamino)-9,10-dihydro-9-methylacridine
3,6-bis(diethylamino)-9-hexyl-9,10-dihydroacridine
3,6-bis(diethylamino)-9,10-dihydro-9-methylacridine
3,6-bis(diethylamino)-9,10-dihydro-9-phenylacridine
3,6-diamino-9-hexyl-9,10-dihydroacridine
3,6-diamino-9,10-dihydro-9-methylacridine
3,6-diamino-9,10-dihydro-9-phenylacridine
3,6-bis(dimethylamino)-9-hexyl-9,10-dihydroacridine
3,6-bis(dimethylamino)-9,10-dihydro-9-methylacridine

### E. Aminophenoxazines

3,7-bis(diethylamino)phenoxazine
9-dimethylamino-benzo[a]phenoxazine

### F. Aminophenothiazines

3,7-bis(benzylamino)phenothiazine

### G. Aminodihydrophenazines

3,7-bis(benzylethylamino)-5,10-dihydro-5-phenylphenazine
3,7-bis(diethylamino)-5-hexyl-5,10-dihydrophenazine
3,7-bis(dihexylamino)-5,10-dihydrophenazine
3,7-bis(dimethylamino)-5-(p-chlorophenyl)-5,10-dihydrophenazine
3,7-diamino-5-(o-chlorophenyl)-5,10-dihydrophenazine
3,7-diamino-5,10-dihydrophenazine
3,7-diamino-5,10-dihydro-5-methylphenazine
3,7-diamino-5-hexyl-5,10-dihydrophenazine-3,7-bis(dimethylamino)-5,10-dihydrophenazine
3,7-bis(dimethylamino)-5,10-dihydro-5-phenylphenazine
3,7-bis(dimethylamino)-5,10-dihydro-5-methylphenazine

### H. Aminodiphenylmethanes

1,4-bis[bis-p(diethylaminophenyl)methyl]piperazine
bis(p-diethylaminophenyl)anilinomethane
bis(p-diethylaminophenyl)-1-benzotriazolylmethane
bis(p-diethylaminophenyl)-2-benzotriazolylmethane
bis(p-diethylaminophenyl)(p-chloroanilino) methane
bis(p-diethylaminophenyl)(2,4-dichloroanilino)methane
bis(p-diethylaminophenyl)(methylamino)methane
bis(p-diethylaminophenyl)(octadecylamino) methane
bis(p-dimethylaminophenyl)aminomethane
bis(p-dimethylaminophenyl)anilinomethane
1,1-bis(dimethylaminophenyl)ethane
1,1-bis(dimethylaminophenyl)heptane
bis(4-methylamino-m-tolyl)aminoethane.

### I. Leuco Indamines

4-amino-4′-dimethylaminodiphenylamine
p-(p-dimethylaminoanilino)phenol

### J. Aminohydrocinnamic Acids (Cyanoethanes, Leuco Methines)

4-amino-.alpha.,.beta.-dicyanohydrocinnamic acid, methyl ester
4-anilino-.alpha.,.beta.-dicyanohydrocinnamic acid, methyl ester
4-(p-chloroanilino)-.alpha.,.beta.-dicyanohydrocinnamic acid, methyl ester
.alpha.-cyano-4-dimethylaminohydrocinnamide
.alpha.-cyano-4-dimethylaminohydrocinnamic acid, methyl ester
.alpha.,.beta.-dicyano-4-diethylaminohydrocinnamic acid, methyl ester
.alpha.,.beta.-dicyano-4-dimethylaminohydrocinnamide
.alpha.,.beta.-dicyano-4-dimethylaminohydrocinnamic acid, methyl ester
.alpha.,.beta.-dicyano-4-dimethylaminohydrocinnamic acid
.alpha.,.beta.-dicyano-4-dimethylaminohydrocinnamic acid, hexyl ester
.alpha.,.beta.-dicyano-4-hexylaminohydrocinnamic acid, methyl ester
.alpha.,.beta..beta.-tricyano-4-hexylaminohydrocinnamic acid, methyl ester
.alpha.,.beta.-dicyano-4-methylaminocinnamic acid, methyl ester
p-(2,2-dicyanoethyl)-N,N-dimethylaniline
4-methoxy-4′-(1,2,2-tricyanoethyl)azobenzene
4-(1,2,2-tricyanoethyl)azobenzene
p-(1,2,2-tricyanoethyl)-N,N-dimethylaniline

### K. Hydrazines

1-(p-diethylaminophenyl)-2-(2-pyridyl)hydrazine
1-(p-dimethylaminophenyl)-2-(2-pyridyl)hydrazine
1-(3-methyl-2-benzothiazolyl)-2-(4-hydroxy-1-naphthyl)hydrazine
1-(2-naphthyl)-2-phenylhydrazine
1-p-nitrophenyl-2-phenylhydrazine
1-(1,3,3-trimethyl-2-indolinyl)-2-(3-N-phenylcarbamoyl-4-hydroxy-1-naphthyl)hydrazine

### L. Leuco Indigoid Dyes

M. Amino-2,3-dihydroanthraquinones
1,4-dianilino-2,3-dihydroanthraquinones
1,4-bis(ethylamino)-2,3-dihydroanthraquinone

### N. Phenethylanilines

N-(2-cyanoethyl)-p-phenethylaniline
N,N-diethyl-p-phenylethylaniline
N,N-dimethyl-p-[2-(1-naphthyl)ethyl]aniline.

According to a still more preferred embodiment of the present invention, the dye D is an amino substituted di- or tri-arylmethane dye, having at least one hydrophilic group. Preferred hydrophilic groups are selected from sulphonic acid group, carboxylic acid group, phosphoric acid group or phosphonic acid group or salts thereof, such as alkali metal salts or ammonium salt; most preferred hydrophilic group is sulphonic acid group or salt thereof.

In another preferred embodiment of the present invention, the dye D is a cationic dye. Cationic dyes are dyes which carry a positive charge in their molecule. Preferred cationic dyes are dyes having a positive charge in the chromophore moiety of the molecule. More preferred cationic dyes are dyes having a positive charge in the chromophore moiety and having a hydrophilic group in a side chain of the chromophoric moiety. Examples of cationic dyes are those mentioned by R. Raue in the Ullmann's Encyclopedia of Industrial Chemistry, edited by Wiley-VCH, volume A5, pagina 369-373 (1986).

The dye D may also be incorporated into a polymer, comprising at least one monomeric unit having a dye D which is covalently or ionically bound to the monomeric unit by a linking group. The dye D in such a polymer is preferably an amino substituted di- or tri-arylmethane dye.

In the present invention, the coating comprises a dye D and a nucleophilic compound Q which interacts with the dye D. Nucleophilic compound is defined as a compound possessing one or more electron-rich sites such as an unshared pair of electrons or ions, the negative end of a polar bond, or pi electrons, and this compound is able to give up electrons, or a share of electrons, to another molecule or ion. Nucleophilic compounds are usually organic compounds comprising a hetero-atom such as O, S, N or P. The interaction between D and Q may be a reaction whereby the compound Q and the dye D are covalently and/or tonically bound to each other, or whereby D and Q form a complex (e.g. by H-bonding). Preferably, the white light optical density of the coating comprising this interaction product DQ is decreased compared to that of the same coating without compound Q. It is presumed that, upon exposure to infrared light or heat, the interaction product DQ is at least partially decomposed and due to this decomposition of DQ, an image can be formed in the coating by release of a dye, which may be the same dye as D. It is also possible that upon heating another colored compound D′, having a different optical spectrum, may be formed than the dye D. In a preferred embodiment of the present invention, the same dye as D is released from the interaction product DQ upon exposure to infrared light or heat.

It is possible that the decomposition reaction of DQ into a release of a dye can be enhanced by addition of a catalyst. However, the addition of a catalyst such as a compound which releases an acid or a base upon heating, also known as photoacid, photobase, thermoacid or thermobase, can reduce the self-life stability of the precursor. In a preferred embodiment of the present invention, compounds which release an acid or a base upon heating, are omitted in the coating of the precursor of the present invention.

A possible explanation for this print-out image may be found in the following mechanism, but this explanation shall not be limiting for the present invention. The compound Q is a nucleophilic compound which interacts with the dye D, which is preferably a cationic dye, and reduces the visible light absorption of the dye, e.g. by forming a leuco dye. Therefore, the nucleophilicity of the compound Q is preferably high enough to form this adduct DQ, especially when DQ is formed in situ in the coating at low pH, e.g. pH<7. Upon heating, the interaction product DQ is decomposed and a dye, possibly D, is released. This release is less likely when the nucleophilicity is high. So, the nucleophilicity of Q is preferably sufficiently low to maintain its leaving capability upon heating (formation of dye); on the other hand, the nucleophilicity of Q is preferably sufficiently high to be able to from a leuco dye adduct DQ, even at a low pH value (pH<7); as a result, the compound Q of the present invention exhibits preferably an acceptable compromise as to its nucleophilicity.

Preferred nucleophilic compounds Q are compounds comprising a thiol group. More preferred nucleophilic compounds are compounds comprising a thiol group and an aminoacid group.

Examples of compounds comprising a thiol group are

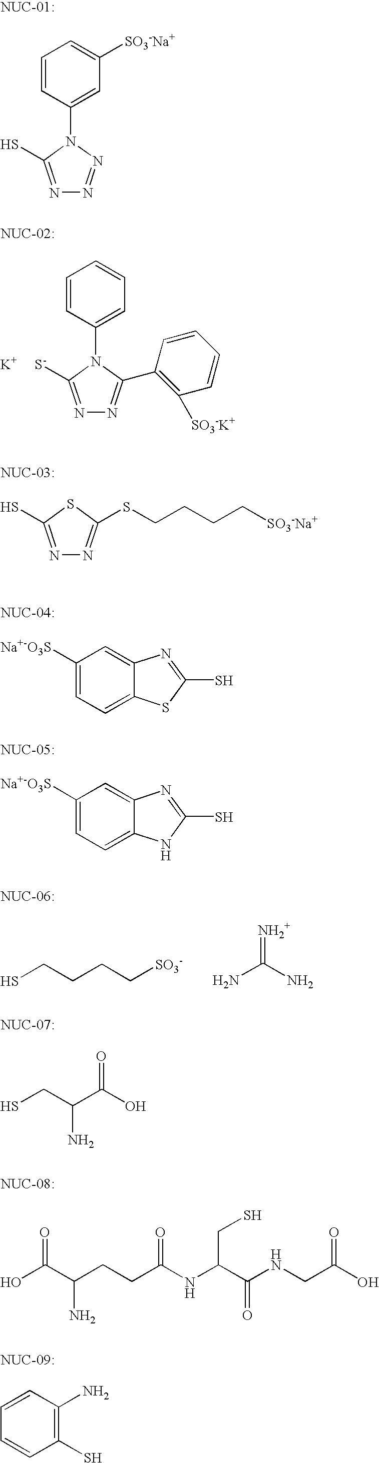

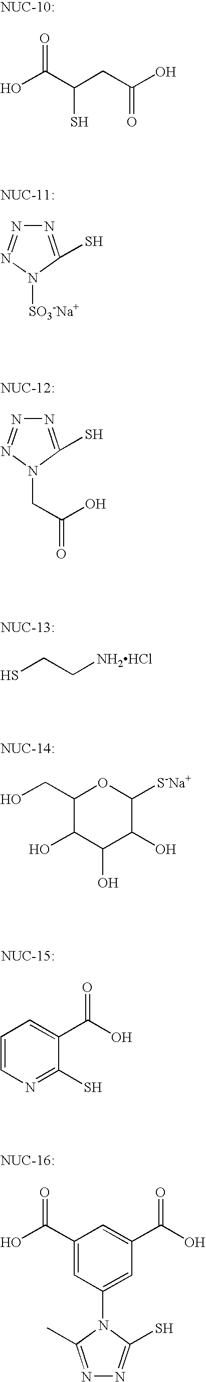

Other nucleophilic compounds are:

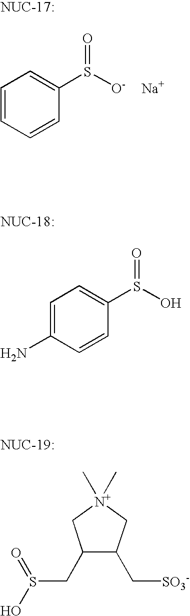

The nucleophilic compound Q may also be incorporated into a polymer, comprising at least one monomeric unit having a nucleophilic group which is covalently or ionically bound to the monomeric unit by a linking group. The nucleophilic group in such a polymer is preferably a triol group. Examples of monomeric units having a nucleophilic group are

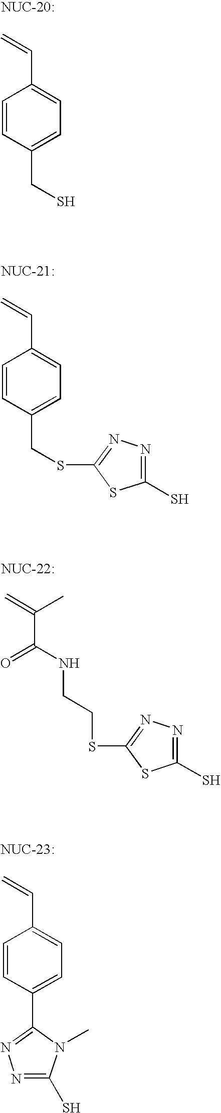

Examples of polymers comprising a monomeric unit having a nucleophilic group are:

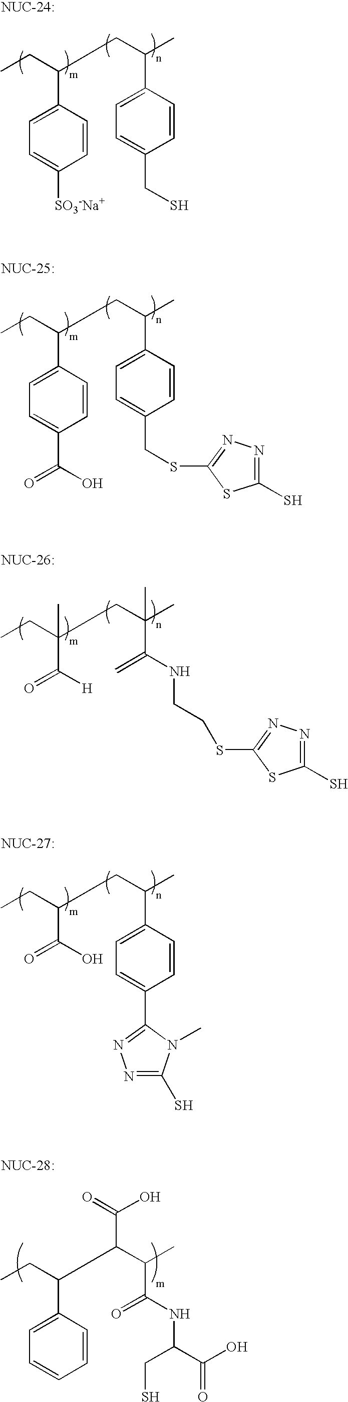

Herein, the indices m and n represent the number of monomeric units in the polymer and usually the monomeric unit with a nucleophilic group is present in an amount of at least 1 unit, preferably between 2 to 100, more preferably between 5 and 20.

The nucleophilic compound Q and the dye D may both be present in the same compound. An example of such a compound is a polymer comprising at least one monomeric unit having a nucleophilic group and at least one monomeric unit having a dye D. The nucleophilic group in this polymer is preferably a triol group and the dye D is preferably an amino substituted di- or tri-arylmethane dye.

In the present invention, a solution or dispersion comprising the dye D and the compound Q is added to the coating and the interaction product DQ is formed in situ during the coating, or the interaction product DQ is first formed in a separate process by mixing D and Q and then added as a solution or dispersion to the coating. The print-out ingredients D and Q or the interaction product DQ may be added to at least one of the layers constituting the coating, such as the image-recording layer, or, optionally a layer on top of the coating or an intermediate layer between the support and the image-recording layer or another intermediate layer between the top layer and the image-recording layer. In alternative embodiment of the present invention, a solution or dispersion comprising the dye D and another solution or dispersion comprising the compound Q are added to two different coatings whereby D and/or Q diffuse together in order to form the interaction product DQ in the coating.

The lithographic printing plate precursor of the present invention is negative-working and develops a lithographic image consisting of hydrophobic and hydrophilic areas at the exposed and non-exposed areas respectively. The hydrophilic areas are defined by the support which has a hydrophilic surface or is provided with a hydrophilic layer. The hydrophobic areas are defined by the coating after exposure to infrared light or heat.

The support may be a sheet-like material such as a plate or it may be a cylindrical element such as a sleeve which can be slid around a print cylinder of a printing press. Preferably, the support is a metal support such as aluminum or stainless steel.

A particularly preferred lithographic support is an electrochemically grained and anodized aluminum support. Graining an anodizing of aluminum supports is well known. The grained aluminum support used in the material of the present invention is preferably an electrochemically grained support. The acid used for graining can be e.g. nitric acid or sulfuric acid. The acid used for graining preferably comprises hydrogen chloride. Also mixtures of e.g. hydrogen chloride and acetic acid can be used. The relation between electrochemical graining and anodizing parameters such as electrode voltage, nature and concentration of the acid electrolyte or power consumption on the one hand and the obtained lithographic quality in terms of Ra and anodic weight (g/m² of Al₂O₃ formed on the aluminum surface) on the other hand is well known. More details about the relation between various production parameters and Ra or anodic weight can be found in e.g. the article “Management of Change in the Aluminium Printing Industry” by F. R. Mayers, published in the ATB Metallurgie Journal, volume 42 nr. 1-2 (2002) pag. 69.

The anodized aluminum support may be subject to a so-called post-anodic treatment to improve the hydrophilic properties of its surface. For example, the aluminum support may be silicated by treating its surface with a sodium silicate solution at elevated temperature, e.g. 95° C. Alternatively, a phosphate treatment may be applied which involves treating the aluminum oxide surface with a phosphate solution that may further contain an inorganic fluoride. Further, the aluminum oxide surface may be rinsed with a citric acid or citrate solution. This treatment may be carried out at room temperature or may be carried out at a slightly elevated temperature of about 30 to 50° C. A further interesting treatment involves rinsing the aluminum oxide surface with a bicarbonate solution. Still further, the aluminum oxide surface may be treated with polyvinylphosphonic acid, polyvinylmethylphosphonic acid, phosphoric acid esters of polyvinyl alcohol, polyvinylsulfonic acid, polyvinylbenzenesulfonic acid, sulfuric acid esters of polyvinyl alcohol, and acetals of polyvinyl alcohols formed by reaction with a sulfonated aliphatic aldehyde.

Another useful post-anodic treatment may be carried out with a solution of polyacrylic acid or a polymer comprising at least 30 mol % of acrylic acid monomeric units, e.g. GLASCOL E15, a polyacrylic acid, commercially available from ALLIED COLLOIDS.

The support can also be a flexible support, which may be provided with a hydrophilic layer, hereinafter called ‘base layer’. The flexible support is e.g. paper, plastic film or aluminum. Preferred examples of plastic film are polyethylene terephthalate film, polyethylene naphthalate film, cellulose acetate film, polystyrene film, polycarbonate film, etc. The plastic film support may be opaque or transparent.

The base layer is preferably a cross-linked hydrophilic layer obtained from a hydrophilic binder cross-linked with a hardening agent such as formaldehyde, glyoxal, polyisocyanate or a hydrolyzed tetra-alkylorthosilicate. The latter is particularly preferred. The thickness of the hydrophilic base layer may vary in the range of 0.2 to 25 μm and is preferably 1 to 10 μm. More details of preferred embodiments of the base layer can be found in e.g. EP-A 1 025 992.

In accordance with a preferred embodiment of the present invention, the coating further comprises hydrophobic thermoplastic polymer particles.

In this type of heat-sensitive coating, the hydrophobic thermoplastic polymer particles fuse or coagulate due to the heat generated during the exposure step, so as to form a hydrophobic phase which corresponds to the printing areas of the printing plate. Coagulation may result from heat-induced coalescence, softening or melting of the thermoplastic polymer particles. There is no specific upper limit to the coagulation temperature of the thermoplastic hydrophobic polymer particles, however the temperature should be sufficiently below the decomposition temperature of the polymer particles. Preferably the coagulation temperature is at least 10° C. below the temperature at which the decomposition of the polymer particles occurs. The coagulation temperature is preferably higher than 50° C., more preferably above 100° C.

In the development step, the non-exposed areas of the image-recording layer are removed by supplying a developing solution without essentially removing the exposed areas, i.e. without affecting the exposed areas to an extent that renders the ink-acceptance of the exposed areas unacceptable. The developing solution may be water, an aqueous solution or an aqueous alkaline solution. The development by supplying a developing solution may be combined with mechanical rubbing, e.g. by a rotating brush. The developing solution can be applied to the plate e.g. by rubbing with an impregnated pad, by dipping, (spin-)coating, spraying, pouring-on, either by hand or in an automatic processing apparatus. The image-wise exposed printing plate precursor may also be developed in an on-press processing by mounting it on a print cylinder of a printing press and supplying an aqueous dampening liquid and/or ink to the surface of the plate while rotating the print cylinder.

Specific examples of suitable hydrophobic thermoplastic polymers are e.g. polyethylene, poly(vinyl chloride), poly(methyl (meth)acrylate), poly(ethyl(meth)acrylate), poly(vinylidene chloride), poly(meth)acrylonitrile, poly(vinyl carbazole), polystyrene or copolymers thereof. Polystyrene and poly(meth)acrylonitrile or their derivatives are highly preferred embodiments. According to such preferred embodiments, the thermoplastic polymer comprises at least 50 wt. % of polystyrene, and more preferably at least 60 wt. % of polystyrene. In order to obtain sufficient resistivity towards organic chemicals, such as the hydrocarbons used in plate cleaners, the hydrophobic thermoplastic polymer preferably comprises at least 5 wt. %, more preferably at least 30 wt. % of nitrogen containing monomeric units or of units which correspond to monomers that are characterized by a solubility parameter larger than 20, such as (meth)acrylonitrile. Suitable examples of such nitrogen containing monomeric units are disclosed in EP-A 1 219 416.

According to a high preferred embodiment, the hydrophobic thermoplastic polymer is a copolymer consisting of styrene and acrylonitrile units in a weight ratio between 1:1 and 5:1 (styrene:acrylonitrile), e.g. in a 2:1 ratio.

The weight average molecular weight of the hydrophobic thermoplastic polymer particles may range from 5,000 to 1,000,000 g/mol. The hydrophobic thermoplastic particles preferably have a number average particle diameter below 200 nm, more preferably between 10 and 100 nm, most preferably between 45 and 63 nm. The amount of hydrophobic thermoplastic polymer particles contained in the image-recording layer is preferably at least 20 wt. %, more preferably at least 70 wt. % and most preferably between 70 wt. % and 85 wt. %.

The hydrophobic thermoplastic polymer particles may be present as a dispersion in an aqueous coating liquid of the image-recording layer and may be prepared by the methods disclosed in U.S. Pat. No. 3,476,937. Another method especially suitable for preparing an aqueous dispersion of the thermoplastic polymer particles comprises:
dissolving the hydrophobic thermoplastic polymer in an organic water immiscible solvent,
dispersing the thus obtained solution in water or in an aqueous medium and
removing the organic solvent by evaporation.

The image recording layer preferably further comprises a hydrophilic binder, e.g. homopolymers and copolymers of vinyl alcohol, acrylamide, methylol acrylamide, methylol methacrylamide, acrylic acid, methacrylic acid, hydroxyethyl acrylate, hydroxyethyl methacrylate or maleic anhydride/vinylmethylether copolymers. The hydrophilicity of the (co)polymer or (co)polymer mixture used is preferably the same as or higher than the hydrophilicity of polyvinyl acetate hydrolyzed to at least an extent of 60 percent by weight, preferably 80 percent by weight.

In accordance with another preferred embodiment of the present invention, the coating further comprises a photopolymer or a photopolymerisable composition.

In this type of heat-sensitive coating, the photopolymer or photopolymerisable composition is hardened, due to the heat generated during the exposure step, so as to form a hydrophobic phase which corresponds to the printing areas of the printing plate. Here, “hardened” means that the coating becomes insoluble or non-dispersible for the gum solution and may be achieved through polymerization and/or crosslinking of the photosensitive coating, optionally followed by a heating step to enhance or to speed-up the polymerization and/or crosslinking reaction. In this optionally heating step, hereinafter also referred to as “pre-heat”, the plate precursor is heated, preferably at a temperature of about 80° C. to 150° C. and preferably during a dwell time of about 5 seconds to 1 minute.

The photopolymerizable coating provided on the support comprises a polymerizable monomer or oligomer and an initiator capable of hardening said monomer or oligomer and, optionally, a sensitizer capable of absorbing light used in the image-wise exposing step.

The coating thickness of the photopolymerizable coating is preferably between 0.1 and 4.0 g/m², more preferably between 0.4 and 2.0 g/m².

In an embodiment, the polymerizable monomer or oligomer may be a monomer or oligomer comprising at least one epoxy or vinyl ether functional group and said initiator may be a Bronsted acid generator capable of generating free acid, optionally in the presence of a sensitizer, upon exposure, hereinafter said initiator also referred to as “cationic photoinitiator” or “cationic initiator”. Suitable polyfunctional epoxy monomers include, for example, 3,4-epoxycyclohexylmethyl-3,4-epoxycyclohex-ane carboxylate, bis-(3,4-epoxycyclohexymethyl)adipate, difunctional bisphenol A epichlorohydrin epoxy resin and multifunctional epichlorohydrinitetraphenylol ethane epoxy resin. Suitable cationic photoinitiators include, for example, triarylsulfonium hexafluoroantimonate, triarylsulfonium hexafluorophosphate, diaryliodonium hexafluoroantimonate, and haloalkyl substituted s-triazine. It is noted that most cationic initiators are also free radical initiators because, in addition to generating Bronsted acid, they also generate free radicals during photo or thermal decomposition.

In another embodiment, the polymerizable monomer or oligomer may be a ethylenically unsaturated compound, having at least one terminal ethylenic group, hereinafter also referred to as “free-radical polymerizable monomer”, and said initiator may be a compound, capable of generating free radical, optionally in the presence of a sensitizer, upon exposure, hereinafter said initiator also referred to as “free radical initiator”.

In a more preferred embodiment of the present invention, the initiator of the photopolymerisable coating is a free radical initiator.

Suitable free-radical polymerizable monomers include, for example, multifunctional (meth)acrylate monomers (such as (meth)acrylate esters of ethylene glycol, trimethylolpropane, pentaerythritol, ethoxylated ethylene glycol and ethoxylated trimethylolpropane, multifunctional urethanated (meth)acrylate, and epoxylated (meth)acrylate), and oligomeric amine diacrylates. The (meth)acrylic monomers may also have other double bond or epoxide group, in addition to (meth)acrylate group. The (meth)acrylate monomers may also contain an acidic (such as carboxylic acid) or basic (such as amine) functionality. Any free radical initiator capable of generating free radical in the presence of a sensitizer upon exposure can be used as a free radical initiator of this invention. Suitable free-radical initiators include, for example, the derivatives of acetophenone (such as 2,2-dimethoxy-2-phenylacetophenone, and 2-methyl-1-[4-(methylthio)phenyl-2-morpholino propan-1-one); benzophenone; benzil; ketocoumarin (such as 3-benzoyl-7-methoxy coumarin and 7-methoxy coumarin); xanthone; thioxanthone; benzoin or an alkyl-substituted anthraquinone; onium salts (such as diaryliodonium hexafluoroantimonate, diaryliodonium triflate, (4-(2-hydroxytetradecyl-oxy)-phenyl)phenyliodonium hexafluoroantimonate, triarylsulfonium hexafluorophosphate, triarylsulfonium p-toluenesulfonate, (3-phenylpropan-2-onyl)triaryl phosphonium hexafluoroantimonate, and N-ethoxy(2-methyl)pyridinium hexafluorophosphate, and onium salts as described in U.S. Pat. Nos. 5,955,238, 6,037,098, and 5,629,354); borate salts (such as tetrabutylammonium triphenyl(n-butyl)borate, tetraethylammonium triphenyl(n-butyl)borate, diphenyliodonium tetraphenylborate, and triphenylsulfonium triphenyl(n-butyl)borate, and borate salts as described in U.S. Pat. Nos. 6,232,038 and 6,218,076); haloalkyl substituted s-triazines (such as 2,4-bis(trichloromethyl)-6-(p-methoxy-styryl)-s-triazine, 2,4-bis(trichloromethyl)-6-(4-methoxy-naphth-1-yl)-s-triazine, 2,4-bis(trichloromethyl)-6-piperonyl-s-triazine, and 2,4-bis(trichloromethyl)-6-[(4-ethoxy-ethylenoxy)-phen-1-yl]-s-triazine, and s-triazines as described in U.S. Pat. Nos. 5,955,238, 6,037,098, 6,010,824 and 5,629,354); and titanocene (bis(etha.9-2,4-cyclopentadien-1-yl)bis[2,6-difluoro-3-(1H-pyrrol-1-yl)phenyl)titanium). Onium salts, borate salts, and s-triazines are preferred free radical initiators. Diaryliodonium salts and triarylsulfonium salts are preferred onium salts. Triarylalkylborate salts are preferred borate salts. Trichloromethyl substituted s-triazines are preferred s-triazines.

In still another embodiment, the polymerizable monomer or oligomer may be a combination of a monomer or oligomer comprising at least one epoxy or vinyl ether functional group and a polymerizable ethylenically unsaturated compound, having at least one terminal ethylenic group, and said initiator may be a combination of a cationic initiator and a free-radical initiator. A monomer or oligomer comprising at least one epoxy or vinyl ether functional group and a polymerizable ethylenically unsaturated compound, having at least one terminal ethylenic group, can be the same compound wherein the compound contains both ethylenic group and epoxy or vinyl ether group. Examples of such compounds include epoxy functional acrylic monomers, such as glycidyl acrylate. The free radical initiator and the cationic initiator can be the same compound If the compound is capable of generating both free radical and free acid. Examples of such compounds include various onium salts such as diaryliodonium hexafluoroantimonate and s-triazines such as 2,4-bis(trichloromethyl)-6-[(4-ethoxyethylenoxy)-phen-1-yl]-s-triazine which are capable of generating both free radical and free acid in the presence of a sensitizer.

The photopolymerizable coating may also comprise a multifunctional monomer. This monomer contains at least two functional groups selected from an ethylenically unsaturated group and/or an epoxy or vinyl ether group. Particular multifunctional monomers for use in the photopolymer coating are disclosed in U.S. Pat. No. 6,410,205, U.S. Pat. No. 5,049,479, EP 1079276, EP 1369232, EP 1369231 EP 1341040, U.S. 2003/0124460, EP 1241002, EP 1288720 and in the reference book including the cited references: Chemistry & Technology UV & EB formulation for coatings, inks & paints—Volume 2-Prepolymers and Reactive Diluents for UV and EB Curable Formulations by N. S. Allen, M. A. Johnson, P. K. T. Oldring, M. S. Salim—Edited by P. K. T. Oldring—1991—ISBN 0 947798102.

The photopolymerizable coating may also comprise a co-initiator. Typically, a co-initiator is used in combination with a free radical initiator and/or cationic initator. Particular co-initiators for use in the photopolymer coating are disclosed in U.S. Pat. No. 6,410,205, U.S. Pat. No. 5,049,479, EP 1079276, 1369232, EP 1369231 EP 1341040, U.S. 2003/0124460, EP 1241002, EP 1288720 and in the reference book including the cited refences: Chemistry & Technology UV & EB formulation for coatings, inks & paints—Volume 3-Photoinitiators for Free Radical and Cationic Polymerisation by K. K. Dietliker—Edited by P. K. T. Oldring—1991—ISBN 0 947798161.

The photopolymerizable coating may also comprise an inhibitor. Particular inhibitors for use in the photopolymer coating are disclosed in U.S. Pat. No. 6,410,205 and EP 1288720.

The photopolymerizable coating may also comprise a binder. The binder can be selected from a wide series of organic polymers. Compositions of different binders can also be used. Useful binders include for example chlorinated polyalkylene (in particular chlorinated polyethylene and chlorinated polypropylene), polymethacrylic acid alkyl esters or alkenyl esters (in particular polymethyl(meth)acrylate, polyethyl(meth)acrylate, polybutyl (meth)acrylate, polyisobutyl(meth)acrylate, polyhexyl (meth)acrylate, poly(2-ethylhexyl)(meth)acrylate and polyalkyl (meth)acrylate copolymers of (meth) acrylic acid alkyl esters or alkenyl esters with other copolymerizable monomers (in particular with (met)acrylonitrile, vinyl chloride, vinylidene chloride, styrene and/or butadiene), polyvinyl chloride (PVC, vinylchloride/(meth)acrylonitrile copolymers, polyvinylidene chloride (PVDC), vinylidene chloride/(meth)acrylonitrile copolymers, polyvinyl acetate, polyvinyl alcohol, poly(meth)acrylonitrile, (meth)acrylonitrile/styrene copolymers, (meth)acrylamide/alkyl (meth)acrylate copolymers, (meth)acrylonitrile/butadiene/styrene (ABS) terpolymers, polystyrene, poly(α-methylstyrene), polyamides, polyurethanes, polyesters, methyl cellulose, ethylcellulose, acetyl cellulose, hydroxy-(C₁-C₄-alkyl)cellulose, carboxymethyl cellulose, polyvinyl formal and polyvinyl butyral. Other useful binders are binders containing carboxyl groups, in particular copolymers containing monomeric units of α,β-unsaturated carboxylic acids or monomeric units of α,β-unsaturated dicarboxylic acids (preferably acrylic acid, methacrylic acid, crotonic acid, vinylacetic acid, maleic acid or itaconic acid). By the term “copolymers” are to be understood in the context of the present invention as polymers containing units of at least 2 different monomers, thus also terpolymers and higher mixed polymers. Particular examples of useful copolymers are those containing units of (meth)acrylic acid and units of alkyl(meth)acrylates, allyl(meth)acrylates and/or (meth)acrylonitrile as well as copolymers containing units of crotonic acid and units of alkyl(meth)acrylates and/or (meth)acrylonitrile and vinylacetic acid/alkyl(meth)acrylate copolymers. Also suitable are copolymers containing units of maleic anhydride or maleic acid monoalkyl esters. Among these are, for example, copolymers containing units of maleic anhydride and styrene, unsaturated ethers or esters or unsaturated aliphatic hydrocarbons and the esterification products obtained from such copolymers. Further suitable binders are products obtainable from the conversion of hydroxyl-containing polymers with intramolecular dicarboxylic anhydrides. Further useful binders are polymers in which groups with acid hydrogen atoms are present, some or all of which are converted with activated isocyanates. Examples of these polymers are products obtained by conversion of hydroxyl-containing polymers with aliphatic or aromatic sulfonyl isocyanates or phosphinic acid isocyanates. Also suitable are polymers with aliphatic or aromatic hydroxyl groups, for example copolymers containing units of hydroxyalkyl(meth)acrylates, allyl alcohol, hydroxystyrene or vinyl alcohol, as well as epoxy resins, provided they carry a sufficient number of free OH groups. Particular useful binder and particular useful reactive binders are disclosed in EP 1 369 232, EP 1 369 231, EP 1 341 040, U.S. 2003/0124460, EP 1 241 002, EP 1 288 720, U.S. Pat. No. 6,027,857, U.S. Pat. No. 6,171,735 and U.S. Pat. No. 6,420,089.

The organic polymers used as binders have a typical mean molecular weight M_{w} between 600 and 200 000, preferably between 1 000 and 100 000. Preference is further given to polymers having an acid number between 10 to 250, preferably 20 to 200, or a hydroxyl number between 50 and 750, preferably between 100 and 500. The amount of binder(s) generally ranges from 10 to 90% by weight, preferably 20 to 80% by weight, relative to the total weight of the non-volatile components of the composition.

Various surfactants may be added into the photopolymerizable coating to allow or enhance the developability of the precursor. Both polymeric and small molecule surfactants can be used. Nonionic surfactants are preferred. Preferred nonionic surfactants are polymers and oligomers containing one or more polyether (such as polyethylene glycol, polypropylene glycol, and copolymer of ethylene glycol and propylene glycol) segments. Examples of preferred nonionic surfactants are block copolymers of propylene glycol and ethylene glycol (also called block copolymer of propylene oxide and ethylene oxide); ethoxylated or propoxylated acrylate oligomers; and polyethoxylated alkylphenols and polyethoxylated fatty alcohols. The nonionic surfactant is preferably added in an amount ranging between 0.1 and 30% by weight of the photopolymerizable coating, more preferably between 0.5 and 20%, and most preferably between 1 and 15%.

The photopolymerizable coating may also comprise a sensitizer, having an absorption spectrum between 750 nm and 1300 nm, preferably between 780 nm and 1200 nm, more preferably between 800 nm and 1100 nm. Examples of suitable sensitizers may be found in EP 1 359 008, including the cited references. Other suitable sensitizers can be selected from the sensitising dyes disclosed in U.S. Pat. No. 6,410,205, U.S. Pat. No. 5,049,479, EP 1 079 276, EP 1 369 232, EP 1 369 231, EP 1 341 040, U.S. 2003/0124460, EP 1 241 002, EP 1 288 720 and in the reference book including the cited references: Chemistry & Technology UV & EB formulation for coatings, inks & paints—Volume 3-Photoinitiators for Free Radical and Cationic Polymerisation by K. K. Dietliker—Edited by P. K. T. Oldring—1991—ISBN 0 947798161.

The heat-sensitive lithographic printing plate precursor may further comprise an infrared absorbing compound. This compound is preferably a dye or pigment having an absorption maximum in the infrared wavelength range and is capable of converting infrared light into heat. Infrared absorbing dyes are more preferred. Particularly useful and specially preferred infrared absorbing dyes are IR-cyanine dyes, IR-merocyanine dyes, IR-methine dyes, IR-naphthoquinone dyes or IR-squarylium dyes. Highly preferred IR-cyanine dyes are the anionic IR-cyanine dyes, specially more preferred those with two sulphonic acids groups. Still more preferably are IR-cyanine dyes with two indolenine and at least two sulphonic acids groups.

The infrared absorbing compound may be present in the image recording layer and/or in another layer, e.g. a top layer or an intermediate layer between the support and the image-recording layer or an intermediate layer between the top layer and the image-recording layer.

The concentration of the infrared absorbing compound in the heat-sensitive coating is preferably between 0.25 and 20% by weight, more preferably between 0.5 and 10% by weight relative to the coating as a whole.

The heat-sensitive coating may also contain other ingredients such as additional binders, development inhibitors or accelerators.

The printing plate precursors used in the present invention are exposed to infrared light, e.g. by means of an infrared laser. Preferably, a laser emitting near infrared light having a wavelength in the range from about 700 to about 1500 nm is used, e.g. a semiconductor laser diode, a Nd:YAG or a Nd:YLF laser. The required laser power depends on the sensitivity of the image recording layer, the pixel dwell time of the laser beam, which is determined by the spot diameter (typical value of modern plate-setters at 1/e² of maximum intensity: 10-25 μm), the scan speed and the resolution of the exposure apparatus (i.e. the number of addressable pixels per unit of linear distance, often expressed in dots per inch or dpi; typical value: 1000-4000 dpi). Two types of laser-exposure apparatuses are commonly used: internal (ITD) and external drum (XTD) plate-setters. ITD plate-setters for thermal plates are typically characterized by a very high scan speed up to 500 m/sec and may require a laser power of several Watts. XTD plate-setters for thermal plates having a typical laser power from about 200 mW to about 1 W operate at a lower scan speed, e.g. from 0.1 to 10 m/sec.

In the development step, the non-exposed areas of the image-recording layer are removed without essentially removing the exposed areas, i.e. without affecting the exposed areas to an extent that renders the ink-acceptance of the exposed areas unacceptable. The non-exposed areas of the image-recording layer may be removed by supplying a developing solution. The developing solution may be water, an aqueous solution or an aqueous alkaline solution. The development may be combined with mechanical rubbing, e.g. by a rotating brush. The developing solution can be applied to the plate e.g. by rubbing in with an impregnated pad, by dipping, (spin-)coating, spraying, pouring-on, either by hand or in an automatic processing apparatus.

In another embodiment of the present invention, the image-wise exposed printing plate precursor may also be developed by mounting it on a print cylinder of a printing press and supplying an aqueous dampening liquid and/or ink to the surface of the plate while rotating the print cylinder. This developing step is also called “on-press developing” or “on-press processing”.

### EXAMPLES

### Comparative Example 1 and Invention Example 1

### Preparation of Lithographic Substrate

A 0.30 mm thick aluminum foil was degreased by immersing the foil in an aqueous solution containing 40 g/l of sodium hydroxide at 60° C. for 8 seconds and rinsed with demineralized water for 2 seconds. The foil was then electrochemically grained during 15 seconds using an alternating current in an aqueous solution containing 12 g/l of hydrochloric acid and 38 g/l of aluminum sulfate (18-hydrate) at a temperature of 33° C. and a current density of 90 A/dm². After rinsing with demineralized water for 2 seconds, the aluminum foil was then desmutted by etching with an aqueous solution containing 155 g/l of sulfuric acid at 70° C. for 4 seconds and rinsed with demineralized water at 25° C. for 2 seconds. The foil was subsequently subjected to anodic oxidation during 13 seconds in an aqueous solution containing 155 g/l of sulfuric acid at a temperature of 45° C. and a current density of 30 A/dm², then washed with demineralized water for 2 seconds and post-treated for 10 seconds with a solution containing 4 g/l of polyvinylphosphonic acid at 40° C., rinsed with demineralized water at 20° C. during 2 seconds and dried.

The support thus obtained was characterized by a surface roughness Ra of 0.21 μm and had an anodic weight of 4.0 g/m² of Al₂O₃.

### Preparation of Coating Solution

Aqueous coating solutions were prepared with the following components:

### Coating Solution 1:

1.872 wt % of Polymer-1; Polymer-1 is a copolymer of styrene and acrylonitile, in a weight ratio of 60/40, having an average particle size of 65 nm;
0.242 wt % of IR-Dye-1; IR-Dye-1 has the following chemical structure:

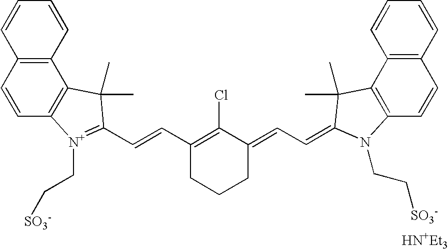

0.242 wt % of Binder-1; Binder-1 is GLASCOL D15, a polyacrylic acid, commercially available from ALLIED COLLOIDS;
0.242 wt % of Dye-2.

Dye-2 has the following chemical structure:

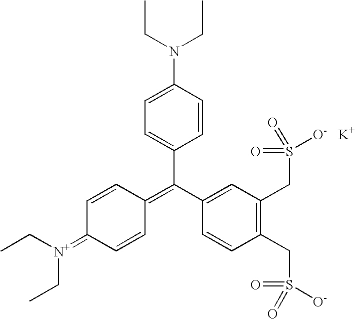

### Coating Solution 2:

1.716 wt % of Polymer-1;
0.221 wt % of IR-Dye-1;
0.221 wt % of Binder-1;
0.221 wt % of Dye-2;
0.221 wt % of NUC-07.

The coating solutions were applied on the lithographic substrate in a at a wet thickness of 30 g/m² and the coated layers were dyed at 60° C. for 2 minutes. Coating solution 1 was used for preparing the precursor for Comparative Example 1 and Coating Solution 2 for Invention Example 1.

Exposure

The plate precursors thus obtained were exposed with a Creo V-head (plate-setter available from Creo, Burnaby, Canada), operating at 200 and 275 mJ/cm² and 150 rpm.

The printing plate precursor of the Comparative Example 1 shows no contrast upon exposure.

The printing plate precursor of the Invention Example 1 shows a good contrast built-up from pale-green to dark-green upon exposure which enables visual inspection of plate prior to processing on the press and starting printing.

On-Press Processing and Printing

After imaging, the plates were mounted on a MO printing press (available from Heidelberger Druckmaschinen AG), and an on-press processing and a print job were started by using K⁺ E800 ink and 4% Combifix XL with 10% isopropanol as a fountain liquid.

With both printing plate precursors good prints were obtained with no wear at all, not even after 100,000 impressions when the press run was stopped.

### Invention Example 2 and Comparative Example 2

### Preparation of the Precursor

The preparation of the lithographic substrate was carried out in the same way as described for Comparative Example 1 and Invention Example 1.

The coating solutions for Invention Example 2 is prepared in the same way as Coating Solution 2 with the exception that NUC-07 has been replaced in the same concentration by NUC-08.

The coating solutions for Comparative Example 2 is prepared in the same way as Coating Solution 2 with the exception that NUC-07 has been replaced in the same concentration by the Additive 1.

The coating and drying method for preparing the precursors for Invention Example 2 and Comparative example 2 was carried out in the same way as described in Comparative Example 1 and Invention Example 1.

Additive 1 has the following chemical structure:

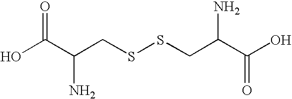

Exposure

The plate precursors thus obtained were exposed with a Creo V-head (plate-setter available from Creo, Burnaby, Canada), operating at 200 and 275 mJ/cm² and 150 rpm.

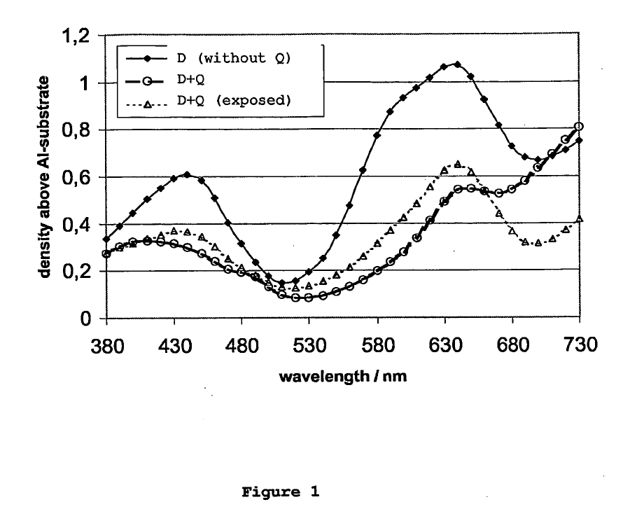

The printing plate precursor of the Invention Example 2 shows a good contrast built-up from pale-green to dark-green upon exposure which enables visual inspection of plate prior to processing on the press and starting printing. The spectral density curve of the coating without Q, with Q and with Q after laser exposure are given in FIG. 1. In this example, [(WLOD-D)−(WLOD-DQ)]0.100%/(WLOD-D) is 43.1%. The CIE color coordinates are measured and calculated following the ASTM E308 method and the following results are obtained (based on illuminant D65): [(L*-nexp)−(L*-exp)]=4.51, [(C*-exp)−(C*-nexp)]=2.6 and ΔE=5.2.

The printing plate precursor of the Comparative Example 2 shows no substantial change in color upon exposure.

On-Press Processing and Printing

After imaging, the plates were mounted on a MO printing press (available from Heidelberger Druckmaschinen AG), and an on-press processing and a print job were started using K⁺ E800 ink and 4% Combifix XL with 10% isopropanol as a fountain liquid.

With both printing plate precursors good prints were obtained with no wear at all, not even after 100,000 impressions when the press run was stopped.

### Invention Examples 3 to 6

Components used in the Invention Examples 3 to 6:
(A) A solution containing 32.8 wt. % of a methyl methacrylate/methacrylic acid-copolymer (ratio methylmethacrylate/methacrylic acid of 4:1 by weight; acid number: 110 mg KOH/g) in 2-butanone (viscosity 105 mm²/s at 25° C.).
(B) A solution containing 86.8 wt. % of a reaction product from 1 mole of 2,2,4-trimethyl-hexamethylenediisocyanate and 2 moles of hydroxyethylmethacrylate (viscosity 3.30 mm²/s at 25° C.).
(C) S0094 (IR-dye commercially available from FEW Chemicals)
(D) S-Triazine
(E) Edaplan LA 411® (1 wt. % in Dowanol PM®, trade mark of Dow Chemical Company).
(F) 2-Butanone.
(G) Propyleneglycol-monomethylether (Dowanol PM®, trade mark of Dow Chemical Company).
(H) Water
(I) Fully hydrolyzed poly(vinyl alcohol)(degree of saponification 98 mol-%, viscosity 6 mPa·s in an aqueous solution of 10 wt. % at 20° C.).
(J) Partially hydrolyzed poly(vinyl alcohol)(degree of saponification 88 mol-%, viscosity 8 mPa·s in an aqueous solution of 10 wt. % at 20° C.).
(K) Partially hydrolyzed poly(vinyl alcohol)(degree of saponification 88 mol-%, viscosity 4 mPa·s in an aqueous solution of 10 wt. % at 20° C.).
(L) A solution of 7.5 wt. % of Dye-2 in water.
(M) A solution of 1 wt. % of IR-Dye-1 in water.
(N) A solution of 3 wt. % of NUC-07 in water.
(O) A solution of 3 wt. % of NUC-08 in water.
(P) A solution of 5 wt. % of Binder-1 in water.
(Q) Lutensol A8 (90 wt. %)(surface active agent commercially available from BASF).

### Preparation and Coating of the Photosensitive Image-Recording Layer

A composition was prepared (pw=parts per weight; wt. %=weight percentage) by mixing the ingredients as specified in Table 1. This composition was coated on an electrochemically roughened and anodically oxidized aluminum sheet, the surface of which has been rendered hydrophilic by treatment with an aqueous solution of poly(vinyl phosphonic) acid (oxide weight 3 g/m²) and was dried at 105° C. The resulting thickness of the layer was 1.5 g/m².

TABLE 1
Composition of the coating solution for the
photosensitive image-recording layer.

| | Parts per |
|---|---|
| Component | weight (g) |
| (A) | 5.77 |
| (B) | 3.14 |
| (C) | 0.13 |
| (D) | 0.34 |
| (E) | 0.57 |
| (F) | 16.72 |
| (G) | 33.32 |

### Preparation and Coating of Overcoat Layers OC-01 to OC-04

On top of the photosensitive image-recording layer, a solution in water of the composition as defined in table 2 was coated and then was dried at 120° C. for 2 minutes.

TABLE 2
Composition of the overcoat layers OC-01 to OC-04.

| | OC-01 | OC-02 | OC-03 | OC-04 |
|---|---|---|---|---|
| | (Invention | (Invention | (Invention | (Invention |
| | Example 3) | Example 4) | Example 5) | Example 6) |
| | Parts per | Parts per | Parts per | Parts per |
| Ingredient | weight (g) | weight (g) | weight (g) | weight (g) |
| (L) | 3.02 | 3.02 | 4.53 | 4.53 |
| (N) | 7.56 | — | 11.33 | — |
| (O) | — | 7.56 | — | 11.33 |
| (M) | 22.67 | 22.67 | 34.00 | 34.00 |
| (K) | — | — | 12.60 | 12.60 |
| (I) | — | — | 11.00 | 11.00 |
| (J) | — | — | 5.54 | 5.54 |
| (P) | 39.73 | 39.73 | — | — |
| (Q) | — | — | 0.04 | 0.04 |
| (H) | 27.02 | 27.02 | 20.90 | 20.90 |

The resulting thickness of each overcoat layer OC-01 to OC-04 on the photosensitive image-recording layer was 0.80 g/m². The precursors of Invention Examples 3 to 6 correspond to the photosensitive image-recording layers with the overcoat layer OC-01 to OC-04.

### Exposure

The plate precursors thus obtained were exposed with a Creo Trendsetter 3244T (plate setter available from Creo, Burnaby, Canada), operating at 300 mJ/cm² and at 150 rpm.

The printing plate precursors of the Invention Examples 3 to 6 show a good contrast built-up from pale-green to dark-green upon exposure which enables visual inspection of the plate prior to processing. The CIE color coordinates are measured and calculated following ASTM E308 method, based on illuminant D65 and also based on illuminant F6, i.e. cool white fluorescent lamp with yellow filter L489, typically used on handling photopolymerizable materials. The results are summarized in Table 3. Herein is ΔL* defined as [(L*-nexp)−(L*-exp)], ΔC* as [(C*-exp)−(C*-nexp)] and ΔE as [(ΔL*)²+(ΔC*)²]^{1/2}.

TABLE 3
Color coordinates for illuminant D65 and for F6 (cool
white fluorescent lamp with yellow filter L489).

| Example | Illuminant | ΔL* | ΔC* | ΔE |
|---|---|---|---|---|
| Invention | D65 | 10.43 | 13.86 | 17.35 |
| Example 3 | F6 | 12.16 | 15.03 | 19.33 |
| Invention | D65 | 6.25 | 5.09 | 8.06 |
| Example 4 | F6 | 6.73 | 5.36 | 8.60 |
| Invention | D65 | 3.63 | 1.09 | 3.79 |
| Example 5 | F6 | 3.53 | −0.02 | 3.53 |
| Invention | D65 | 3.42 | −1.43 | 3.71 |
| Example 6 | F6 | 3.17 | −2.12 | 3.81 |

The Invention Examples 3 to 6 give a high value for ΔE and also for ΔL*, resulting in a good quality of the print-out images.

1-10. (canceled)

11: A method for making a negative-working heat-sensitive lithographic printing plate precursor comprising the steps of:
(i) providing a support having a hydrophilic surface or a hydrophilic layer; and
(ii) applying on the support a coating which includes a product DQ; wherein the product DQ is obtained by:
a step of coating a solution or dispersion including a nucleophilic compound Q and a dye D selected from the group consisting of di- or tri-arylmethane dyes, cyanine dyes, styryl dyes, and merostyryl dyes; or
a step of coating a solution or dispersion including the compound Q and coating another solution or dispersion including the dye D; wherein
D and Q interact to form interaction product DQ, having a white light optical density which is lower than a white light optical density of dye D; and
the interaction product DQ is capable of at least partially releasing a dye directly after exposure to infrared light or heat, thereby forming a visible image in the coating.

12: The method according to claim 11, wherein dye D is a di- or tri-arylmethane dye having an amino substituted aryl group.

13: The method according to claim 11, wherein dye D has a positively charged chromophore moiety.

14: The method according to claim 12, wherein dye D has a positively charged chromophore moiety.

15: The method according to claim 11, wherein the nucleophilic compound Q is a compound including a thiol group.

16: The method according to claim 12, wherein the nucleophilic compound Q is a compound including a thiol group.

17: The method according to claim 13, wherein the nucleophilic compound Q is a compound including a thiol group.

18: The method according to claim 14, wherein the nucleophilic compound Q is a compound including a thiol group.

19: The method according to claim 11, wherein the coating further includes hydrophobic thermoplastic polymer particles.

20: The method according to claim 12, wherein the coating further includes hydrophobic thermoplastic polymer particles.

21: The method according to claim 15, wherein the coating further includes hydrophobic thermoplastic polymer particles.

22: The method according to claim 16, wherein the coating further includes hydrophobic thermoplastic polymer particles.

23: The method according to claim 19, wherein the hydrophobic thermoplastic polymer particles are selected from polyethylene, polyvinylchloride, polyvinylidenechloride, polymethyl(meth)acrylate, polyethyl(meth)acrylate, poly(meth)acryonitrile, polystyrene, or copolymers thereof.

24: The method according to claim 20, wherein the hydrophobic thermoplastic polymer particles are selected from polyethylene, polyvinylchloride, polyvinylidenechloride, polymethyl(meth)acrylate, polyethyl(meth)acrylate, poly(meth)acryonitrile, polystyrene, or copolymers thereof.

25: The method according to claim 21, wherein the hydrophobic thermoplastic polymer particles are selected from polyethylene, polyvinylchloride, polyvinylidenechloride, polymethyl(meth)acrylate, polyethyl(meth)acrylate, poly(meth)acryonitrile, polystyrene, or copolymers thereof.

26: The method according to claim 22, wherein the hydrophobic thermoplastic polymer particles are selected from polyethylene, polyvinylchloride, polyvinylidenechloride, polymethyl(meth)acrylate, polyethyl(meth)acrylate, poly(meth)acryonitrile, polystyrene, or copolymers thereof.

27: The method according to claim 11, wherein the coating further includes a photopolymer or a photopolymerizable composition.

28: The method according to claim 12, wherein the coating further includes a photopolymer or a photopolymerizable composition.

29: The method according to claim 15, wherein the coating further includes a photopolymer or a photopolymerizable composition.

30: The method according to claim 16, wherein the coating further includes a photopolymer or a photopolymerizable composition.

31: The method according to claim 27, wherein the photopolymer or the photopolymerizable composition is sensitive to infrared light or heat.

32: The method according to claim 28, wherein the photopolymer or the photopolymerizable composition is sensitive to infrared light or heat.

33. The method according to claim 29, wherein the photopolymer or the photopolymerizable composition is sensitive to infrared light or heat.

34: The method according to claim 30, wherein the photopolymer or the photopolymerizable composition is sensitive to infrared light or heat.

35: A method of making a negative-working lithographic printing plate comprising the steps of:
providing a negative-working heat-sensitive lithographic printing plate precursor formed according to the method of claim 11;
image-wise exposing the coating of the printing plate precursor to infrared light or heat, whereby a visible image is obtained; and
developing the image-wise exposed printing plate precursor.

36: A method of making a negative-working lithographic printing plate comprising the steps of:
providing a negative-working heat-sensitive lithographic printing plate precursor formed according to the method of claim 11;
image-wise exposing the coating of the printing plate precursor to infrared light or heat, whereby a visible image is obtained; and
mounting the image-wise exposed printing plate precursor on a printing press and developing the precursor in an on-press developing step.

37: A method of making a negative-working lithographic printing plate comprising the steps of:
providing a negative-working heat-sensitive lithographic printing plate precursor formed according to the method of claim 19;
image-wise exposing the coating of the printing plate precursor to infrared light or heat, whereby a visible image is obtained; and
developing the image-wise exposed printing plate precursor.

38: A method of making a negative-working lithographic printing plate comprising the steps of:
providing a negative-working heat-sensitive lithographic printing plate precursor formed according to the method of claim 27;
image-wise exposing the coating of the printing plate precursor to infrared light or heat, whereby a visible image is obtained; and
developing the image-wise exposed printing plate precursor.

39: A method of making a negative-working lithographic printing plate comprising the steps of:
providing a negative-working heat-sensitive lithographic printing plate precursor formed according to the method of claim 19;
image-wise exposing the coating of the printing plate precursor to infrared light or heat, whereby a visible image is obtained; and
mounting the image-wise exposed printing plate precursor on a printing press and developing the precursor in an on-press developing step.

40: A method of making a negative-working lithographic printing plate comprising the steps of:
providing a negative-working heat-sensitive lithographic printing plate precursor formed according to the method of claim 27;
image-wise exposing the coating of the printing plate precursor to infrared light or heat, whereby a visible image is obtained; and
mounting the image-wise exposed printing plate precursor on a printing press and developing the precursor in an on-press developing step.

41: A negative-working heat-sensitive lithographic printing plate precursor comprising:
(i) a support having a hydrophilic surface or a hydrophilic layer; and
(ii) a coating including an image-recording layer; wherein
the coating further includes a dye D and a compound Q which interacts with the dye, or an interaction product DQ between the dye D and the compound Q; wherein as a result of the interaction a white light optical density of the coating (WLOD-DQ) is decreased compared to a white light optical density of the same coating without compound Q (WLOD-D); and
the coating is capable of providing a visible image directly after exposure to infrared light or heat whereby the CIE 1976 lightness of the exposed areas (L*-exp) is decreased compared to the CIE 1976 lightness of the non-exposed areas (L*-nexp), and/or the CIE 1976 chroma of the exposed areas (C*-exp) is increased compared to the CIE 1976 chroma of the non-exposed areas (C*-nexp), and whereby the CIE 1976 color distance ΔE, measured between the exposed and non-exposed areas, has a value of at least 3.

42: The precursor according to claim 41, wherein the decrease of L*-exp compared to L*-nexp, defined as [(L*-nexp)−(L*-exp)], is at least 2.

43: The precursor according to claim 41, wherein the decrease of WLOD-DQ compared to the WLOD-D, defined as [(WLOD-D)−(WLOD-DQ)]×100%/(WLOD-D), is at least about 25%.

44: A method of making a lithographic printing plate comprising the steps of:
providing a negative-working heat-sensitive lithographic printing plate precursor according to claim 41;
image-wise exposing the coating to infrared light or heat, whereby the CIE 1976 lightness of the exposed areas (L*-exp) is decreased compared to the CIE 1976 lightness of the non-exposed areas (L*-nexp), and/or the CIE 1976 chroma of the exposed areas (C*-exp) is increased compared to the CIE 1976 chroma of the non-exposed areas (C*-nexp), and whereby the CIE 1976 color distance ΔE, measured between the exposed and non-exposed areas, has a value of at least 3, thereby obtaining a visible image; and
developing the image-wise exposed printing plate precursor.

45: A method of making a lithographic printing plate comprising the steps of:
providing a negative-working heat-sensitive lithographic printing plate precursor according to claim 41;
image-wise exposing the coating to infrared light or heat, whereby the CIE 1976 lightness of the exposed areas (L*-exp) is decreased compared to the CIE 1976 lightness of the non-exposed areas (L*-nexp), and/or the CIE 1976 chroma of the exposed areas (C*-exp) is increased compared to the CIE 1976 chroma of the non-exposed areas (C*-nexp), and whereby the CIE 1976 color distance ΔE, measured between the exposed and non-exposed areas, has a value of at least 3, thereby obtaining a visible image; and
mounting the image-wise exposed printing plate precursor on a printing press and developing the precursor in an on-press developing step.
